(19) United States
(12) Patent Application Publication
(10) Pub. No.: US 2025/0267880 A1
(43) Pub. Date: Aug. 21, 2025

(54) MIM STRUCTURE WITH ROUNDED SIDEWALL AND FABRICATING METHOD OF THE SAME

(71) Applicant: UNITED MICROELECTNONICS CORP., Hsin-Chu City (TW)

(72) Inventors: Wen-Wen Zhang, Changhua County (TW); Ya-Jyuan Hung, Kaohsiung City (TW); Ming-Chou Lu, Pingtung County (TW); Kun-Chen Ho, Tainan City (TW)

(73) Assignee: UNITED MICROELECTNONICS CORP., Hsin-Chu City (TW)

(21) Appl. No.: 18/596,632

(22) Filed: Mar. 6, 2024

(30) Foreign Application Priority Data
Feb. 16, 2024 (TW) 113105560

(51) Int. Cl. H01L 23/522; H01L 23/532

(52) U.S. Cl. CPC H10D 1/042; H01L 23/5223; H01L 23/53295; H10D 1/716

(57) ABSTRACT

An MIM capacitor structure with a rounded sidewall includes a stacked layer. The stacked layer includes at least one silicon-containing material layer and at least one oxygen-containing silicon compound layer alternately stacked, and a trench is disposed in the stacked layer. The trench has a rounded sidewall and a vertical sidewall. The vertical sidewall and the rounded sidewall are connected to each other. An MIM capacitor is disposed in the trench and contacts the trench. An insulating layer fills the trench and seals an opening of the trench. An air gap is disposed in the insulating layer.

### BACKGROUND OF THE INVENTION

### 1. Field of the Invention

The present invention relates to a metal-insulator-metal (MIM) capacitor, in particular to an MIM capacitor with a rounded sidewall.

### 2. Description of the Prior Art

MIM capacitors are not only used to filter noise in radio frequency circuits, or as load components in digital circuits, it is also widely used in general integrated circuit and circuit board manufacturing processes. In recent years, with the development of semiconductor integrated circuit process technology, the minimum width of devices on semiconductor substrates has gradually become smaller; therefore the density of integrated circuits per unit area is increased.

Due to the increase in the density of memory cell, the space occupied by a capacitor per unit area for charge storage will become smaller. Therefore, it is necessary to develop capacitors with small size but high capacitance. Currently, how to form MIM capacitors with higher capacitance under high density has become a goal for semiconductor field.

### SUMMARY OF THE INVENTION

In view of this, the present invention provides an MIM capacitor structure with a rounded sidewall and a fabricating method of the same to form an MIM capacitor with high capacitance.

According to a preferred embodiment of the present invention, an MIM capacitor structure with a rounded sidewall includes a stacked layer, wherein the stacked layer includes at least a silicon-containing material layer and at least one oxygen-containing silicon compound layer stacked alternately. A trench is disposed in the stacked layer, wherein the trench has a rounded sidewall and a vertical sidewall, and the vertical sidewall and the rounded sidewall are connected to each other. An MIM capacitor is disposed in the trench and contacts the trench. An insulating layer fills in the trench and seals up an opening of the trench. An air gap is disposed in the insulating layer.

According to another preferred embodiment of the present invention, a fabricating method of an MIM capacitor structure with a rounded sidewall includes providing an oxygen-containing silicon compound layer and a silicon-containing material layer. Next, a first etching is performed to etch the oxygen-containing silicon compound layer and the silicon-containing material layer to form a trench. Later, a second etching is performed to etch the oxygen-containing silicon compound layer to laterally expand a portion of a sidewall of the trench to form a rounded sidewall. After forming the rounded sidewall, an MIM capacitor is formed to fill in and contact the trench. Finally, after forming the MIM capacitor, an insulating layer is formed to fill the trench and seal up the opening of the trench, wherein the insulating layer defines an air gap.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 depict a fabricating method of an MIM capacitor structure with a rounded sidewall according to a first preferred embodiment of the present invention, wherein:

FIG. 1 depicts a stacked layer;

FIG. 2 is a fabricating stage in continuous of FIG. 1; and

FIG. 3 is a fabricating stage in continuous of FIG. 2.

FIG. 4 depicts an MIM capacitor structure with a rounded sidewall according to a second preferred embodiment of the present invention.

FIG. 5 depicts an MIM capacitor structure with a rounded sidewall according to a third preferred embodiment of the present invention.

FIG. 6 depicts an MIM capacitor structure with a rounded sidewall according to a fourth preferred embodiment of the present invention.

FIG. 7 depicts an MIM capacitor structure with a rounded sidewall according to a fifth preferred embodiment of the present invention.

FIG. 8 depicts an MIM capacitor structure with a rounded sidewall according to a sixth preferred embodiment of the present invention.

### DETAILED DESCRIPTION

FIG. 1 to FIG. 3 depict a fabricating method of an MIM capacitor structure with a rounded sidewall according to a first preferred embodiment of the present invention.

As shown in FIG. 1, a substrate 1 is provided. A stacked layer 10 is disposed on the substrate 1. The substrate 1 includes a silicon substrate, a germanium substrate, a gallium arsenide substrate, a silicon germanium substrate, an indium phosphide substrate, a gallium nitride substrate, a silicon carbide substrate or a silicon on insulator (SOI) substrate. The stacked layer 10 includes at least one silicon-containing material layer and at least one oxygen-containing silicon compound layer alternately stacked on one another. For example, a first silicon-containing material layer 12a, a first oxygen-containing silicon compound layer 14a, a second silicon-containing material layer 12b, a second oxygen-containing silicon compound layer 14b and a third silicon-containing material layer 12c disposed from bottom to top in sequence. The number of layers in the stacked layer 10 can be adjusted according to different needs, and the material of the silicon-containing material layer and the material of the oxygen-containing silicon compound layer can also be changed according to different requirements. However, the silicon-containing material layer and the oxygen-containing silicon compound layer adjacent to each other need to have different etching selectivity ratios with respective to the same etchant. According to a preferred embodiment of the present invention, the first silicon-containing material layer 12a, the second silicon-containing material layer 12b and the third silicon-containing material layer 12c may be silicon nitride, poly-crystalline silicon, single-crystalline silicon or amorphous silicon. The first oxygen-containing silicon compound layer 14a and the second oxygen-containing silicon compound layer 14b are preferably silicon oxide.

Next, a first etching 16a is performed to etch the third silicon-containing material layer 12c, the second oxygen-containing silicon compound layer 14b, the second silicon-containing material layer 12b and the first oxygen-containing silicon compound layer 14a to form a trench 18a in the third silicon-containing material layer 12c, the second oxygen-containing silicon compound layer 14b, the second silicon-containing material layer 12b and the first oxygen-containing silicon compound layer 14a. The trench 18a uses the first silicon-containing material layer 12a as a bottom. The width W of the opening of the trench 18a is preferably between 100 and 1000 nanometers. In addition, the sidewall of the trench 18a is perpendicular to the top surface of the stacked layer 10. The sidewall of the trench 18a in the third silicon-containing material layer 12c, the second oxygen-containing silicon compound layer 14b, the second silicon-containing material layer 12b and the first oxygen-containing silicon compound layer 14a are aligned with each other. The first etching 16a is preferably a dry etching.

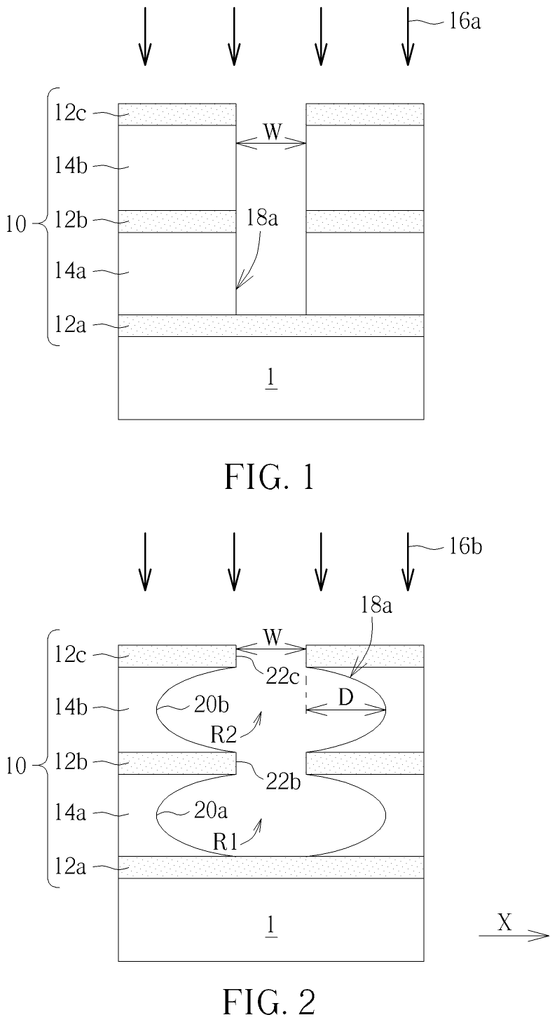

As shown in FIG. 2, a second etching 16b is performed to etch the second oxygen-containing silicon compound layer 14b and the first oxygen-containing silicon compound layer 14a to laterally expand part of the trench 18a. The distance D laterally expanded is preferably 0.01 to 1 times of the width W of the opening. The second etching 16b includes a wet etching. The second etching 16b preferably include only the wet etching. In details, the second etching 16b is to selectively etch silicon oxide and not etch silicon nitride or silicon. The wet etching can use dilute hydrofluoric acid as the etchant. According to a preferred embodiment of the present invention, the etching selectivity ratio of silicon oxide to silicon nitride of the etchant is 16.9. Therefore, while the second oxygen-containing silicon compound layer 14b and the first oxygen-containing silicon compound layer 14a are etched by the etchant, the surfaces of the third silicon-containing material layer 12c, the second silicon-containing material layer 12b and the first silicon-containing material layer 12a can be considered as not etched by the etchant. When the second etching 16b is performed, the trench 18a in the second oxygen-containing silicon compound layer 14b and the first oxygen-containing silicon compound layer 14a is etched to be expanded laterally to form a rounded sidewall 20a and a rounded sidewall 20b. The trench 18a in the third silicon-containing material layer 12c and the second silicon-containing material layer 12b can be regarded as not being etched. Therefore, the sidewall of the trench 18a in the third silicon-containing material layer 12c and the second silicon-containing material layer 12b maintain vertical, and the sidewall of the trench 18a in the third silicon-containing material layer 12c and the sidewall of the trench 18a in the second silicon-containing material layer 12b are respectively defined as a vertical sidewall 22c and a vertical sidewall 22b. The rounded sidewall 20b is connected to the vertical sidewall 22c and the vertical sidewall 22b. The rounded sidewall 20a and the vertical sidewall 22b are connected. The above-mentioned lateral expansion refers to an expansion along the horizontal direction X parallel to the top surface of the third silicon-containing material layer 12c.

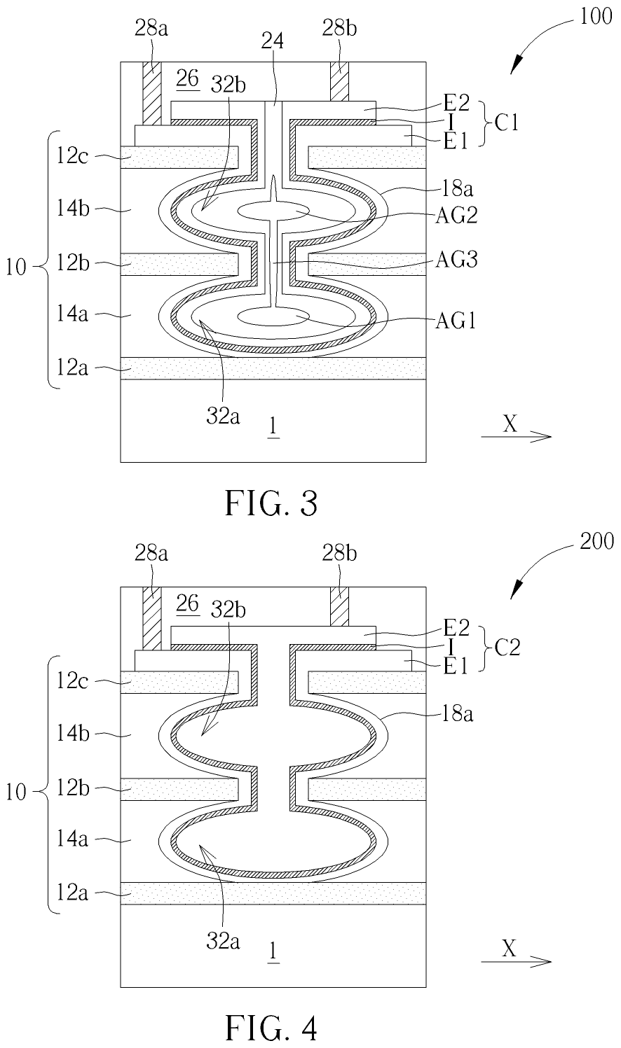

As shown in FIG. 3, a silicon oxide liner (not shown) may be optionally formed to cover the trench 18a and the top surface of the third silicon-containing material layer 12c. If the third silicon-containing material layer 12c, the second silicon-containing material layer 12b and the first silicon-containing material layer 12a are made of silicon nitride, the silicon oxide lining layer can be omitted. If the third silicon-containing material layer 12c, the second silicon-containing material layer 12b and the first silicon-containing material layer 12a are poly-crystalline silicon, single-crystalline silicon or amorphous silicon, the silicon oxide lining layer is required. In this embodiment, the third silicon-containing material layer 12c, the second silicon-containing material layer 12b and the first silicon-containing material layer 12a are exemplified as silicon nitride and the silicon oxide liner is omitted. Then, a first electrode E1, a capacitor dielectric layer I and a second electrode E2 are formed in sequence to cover the trench 18a and the top surface of the third silicon-containing material layer 12c. Later, an insulating layer 24 is formed to fill the trench 18a. The insulating layer 24 seals up the opening of the trench 18a and forms air gaps AG1/AG2/AG3 in the insulating layer 24.

After that, the first electrode E1, the capacitor dielectric layer I, the second electrode E2 and the insulating layer 24 are patterned to make the length of the first electrode E1 on the third silicon-containing material layer 12c is greater than the length of the second electrode E2 on the third silicon-containing material layer 12c along the horizontal direction X. Moreover, the first electrode E1, the capacitor dielectric layer I, the second electrode E2 and the insulating layer 24 all protrude above the opening of the trench 18a. The first electrode E1, the capacitor dielectric layer I, and the second electrode E2 constitute the MIM capacitor C1. Then, a dielectric layer 26 is formed to cover the third silicon-containing material layer 12c. Subsequently, contact plugs 28a/28b are formed in dielectric layer 26. The contact plug 28a contacts the first electrode E1, and the contact plug 28b contacts the second electrode E2. Now, an MIM capacitor structure 100 with a rounded sidewall of the present invention is completed.

According to the second preferred embodiment of the present invention, the insulating layer 24 may not be formed, and the remaining space of the trench 18a can be filled up with the second electrode E2. FIG. 4 shows fabricating steps in continuous of the steps in FIG. 2. Elements which are substantially the same as those in the embodiment of FIG. 4 are denoted by the same reference numerals in FIG. 3; an accompanying explanation is therefore omitted. As shown in FIG. 4, a first electrode E1 and a capacitor dielectric layer I are sequentially formed to cover the trench 18a and the top surface of the third silicon-containing material layer 12c. Later, a second electrode E2 is formed to fill up the remaining space of the trench 18a. The following steps are the same as those in FIG. 3, the steps may include patterning the first electrode E1, the capacitor dielectric layer I and the second electrode E2. The first electrode E1, the capacitor dielectric layer I and the second electrode E2 form the MIM capacitor C2. Next, the dielectric layer 26 and contact plugs 28a/28b are formed. Now, an MIM capacitor structure 200 with a rounded sidewall of the present invention is completed.

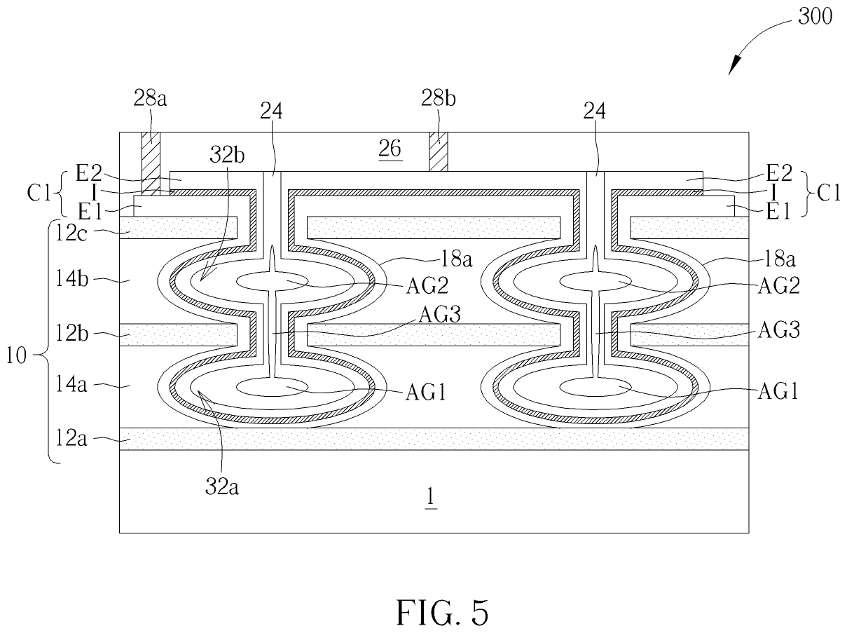

When the first etching 16a is performed in FIG. 1, numerous trenches 18a may also be formed simultaneously. Subsequently, the second etching 16b is performed followed by forming the first electrode E1, the second electrode E2 and the capacitor dielectric layer I. In this way, numerous MIM capacitors can be formed and connected in series. For example, according to the third preferred embodiment of the present invention, as shown in FIG. 5, the manufacturing process of the MIM capacitor structure 300 with a rounded sidewall includes using the first etching 16a to form two trenches 18a. Later, a second etching 16b is performed. After that, the steps similar to those in FIG. 3 are performed. That is, the first electrode E1, the capacitor dielectric layer I, the second electrode E2 and the insulating layer 24 are formed to fill in the trenches 18a. Then, the dielectric layer 26 and contact plugs 28a/28b are then formed. The MIM capacitor structure 300 is exemplified as two capacitor connected in series. Elements in FIG. 5 which are substantially the same as those in the embodiment of FIG. 3 are denoted by the same reference numerals; an accompanying explanation is therefore omitted.

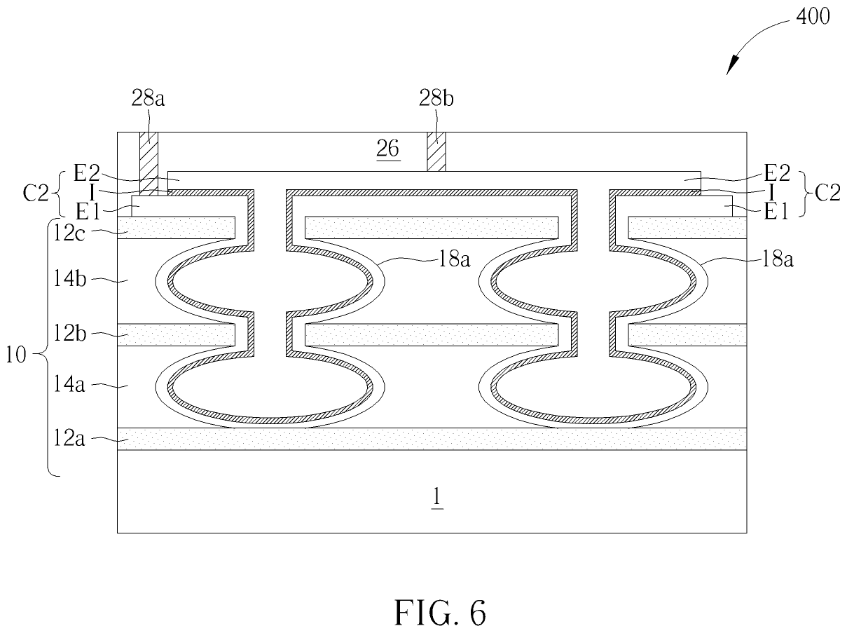

According to a fourth preferred embodiment of the present invention, as shown in FIG. 6, the fabricating process of an MIM capacitor structure 400 with a rounded sidewall includes performing the first etching 16a to form two trenches 18a. Later, the second etching 16b is performed followed by using the steps in FIG. 4 such as forming the first electrode E1, the capacitor dielectric layer I and the second electrode E2 to form two MIM capacitors C2. Next, the dielectric layer 26 and contact plugs 28a/28b are formed. Elements in FIG. 6 which are substantially the same as those in the embodiment of FIG. 4 are denoted by the same reference numerals; an accompanying explanation is therefore omitted.

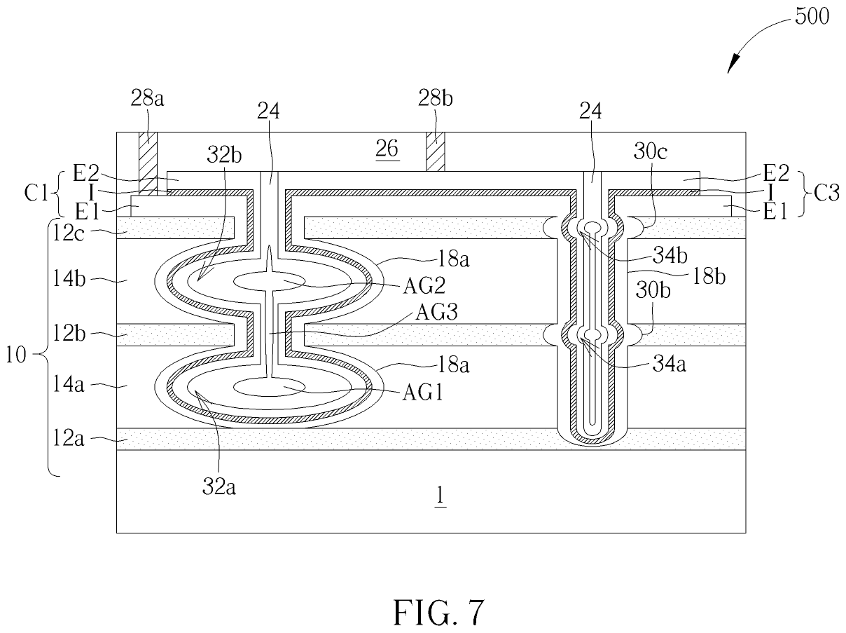

According to a fifth preferred embodiment of the present invention, as shown in FIG. 7, an MIM capacitor structure 500 with rounded a sidewall is formed by using the first etching 16a illustrated in FIG. 1 to form two trenches 18a/18b. Later, the trench 18a in the first oxygen-containing silicon compound layer 14a and the second oxygen-containing silicon compound layer 14b is laterally enlarged by the second etching 16b illustrated in FIG. 2. The second etching 16b only etches the trench 18a. Later, an additional third etching is performed. The third etching only etches the trench 18b in the silicon nitride, poly-crystalline silicon, single-crystalline silicon or amorphous silicon, and does not etch the silicon oxide nor the entire trench 18a. In this way, the trench 18b in the third silicon-containing material layer 12c and the second silicon-containing material layer 12b is laterally widen by the third etching and the bottom of the trench 18b is also expand toward the first silicon-containing material layer 12a. Therefore, the bottom of the trench 18b also becomes rounded. The sidewall of the trench 18b in the third silicon-containing material layer 12c and the second silicon-containing material layer 12b are rounded sidewalls 30c/30b. After that, the steps similar to those in FIG. 3 are performed. That is, the first electrode E1, the capacitor dielectric layer I, the second electrode E2 and the insulating layer 24 are formed to fill in the trench 18a and the trench 18b. Then, the dielectric layer 26 and contact plugs 28a/28b are formed. In this way, an MIM capacitor C1 and an MIM capacitor C3 can be formed. The MIM capacitor C1 and the MIM capacitor C3 are connected to each other in series. Elements in FIG. 7 which are substantially the same as those in the embodiment of FIG. 3 are denoted by the same reference numerals; an accompanying explanation is therefore omitted.

As shown in FIG. 3, an MIM capacitor structure 100 with a rounded sidewall includes a stacked layer 10. The stacked layer 10 preferably has no transistor disposed within, and the substrate 1 preferably has no transistors or active devices disposed on it. The MIM capacitor structure 100 with a rounded sidewall is preferably applied on an interposer. For example, the substrate 1 and the stacked layer 10 constitute an interposer, and the MIM capacitor structure 100 with a rounded sidewall is disposed on the stacked layer 10. The stacked layer 10 includes at least one silicon-containing material layer and at least one oxygen-containing silicon compound layer stacked alternately. The silicon-containing material layer may include a first silicon-containing material layer 12a, a second silicon-containing material layer 12b and a third silicon-containing material layer 12c. The oxygen-containing silicon compound layer may include a first oxygen-containing silicon compound layer 14a and a second oxygen-containing silicon compound layer 14b. The first oxygen-containing silicon compound layer 14a, the second silicon-containing material layer 12b, the second oxygen-containing silicon compound layer 14b and the third silicon-containing material layer 12c are arranged in sequence from bottom to top. The thickness of each of the silicon-containing material layer is preferably 20 to 50 nanometers. The thickness of each of the oxygen-containing silicon compound layer is 1 to 10 times of each of the silicon-containing material layer. The silicon-containing material layer is preferably poly-crystalline silicon, single-crystalline silicon or amorphous silicon. The oxygen-containing silicon compound layer is preferably silicon oxide.

Please also refer to FIG. 2. A trench 18a is disposed in the stacked layer 10. The trench 18a has rounded sidewalls 20a/20b and vertical sidewalls 22b/22c. The vertical sidewalls 20a/20b are connected to the rounded sidewalls 22b/22c. In details, two sidewalls of the trench 18a in the first oxygen-containing silicon compound layer 14a and the second oxygen-containing silicon compound layer 14b are respectively rounded sidewalls 20a/20b. Two sidewalls of the trench 18a in the second silicon-containing material layer 12b are vertical sidewalls 22b. Two sidewalls of the trench 18a in the third silicon-containing material layer 12c are vertical sidewalls 22c. Along a horizontal direction X, the rounded sidewalls 20a/20b are respectively concave toward the first oxygen-containing silicon compound layer 14a and the second oxygen-containing silicon compound layer 14b. Because two sidewalls of the trench 18a are rounded sidewalls 20a/20b, a widen region R1 is defined between the rounded sidewalls 20a in the first oxygen-containing silicon compound layer 14a, and a widen region R2 is defined between the rounded sidewalls 20b in the second oxygen-containing silicon compound layer 14b. Moreover, an MIM capacitor C1 is disposed in the trench 18a and contacts the trench 18a. The MIM capacitor C1 includes a first electrode E1, a capacitor dielectric layer I and a second electrode E2. Since the MIM capacitor C1 conformally fills the trench 18a, the MIM capacitor C1 also has rounded sidewalls 32a/32b respectively in the first oxygen-containing silicon compound layer 14a and the second oxygen-containing silicon compound layer 14b. An insulating layer 24 fills the trench 18a and seals up the opening of the trench 18a. The air gaps AG1/AG2/AG3 are disposed in the insulating layer 24. The air gaps AG1/AG2 are respectively located in the insulating layer 24 of the widen region R1 and widen region R2. An air gap AG3 is also disposed in the insulating layer 24 between the vertical sidewalls 22b. The air gaps AG1/AG2 connect to the air gap AG3. The multiple relationship between the width W of the opening of the trench 18a and the distance D of the lateral expansion of the trench 18a mentioned above is to allow the first electrode E1, the capacitor dielectric layer I and the second electrode E2 to cover the trench 18a conformally, and the make sure the trench 18a sealed up only after the insulating layer 24 completely cover the surface of the second electrode E2 in the trench 18a. Completely covering the surface of the second electrode E2 in the trench 18a by using the insulating layer 24 can protect the second electrode E2 from oxidation.

The first electrode E1 and the second electrode E2 respectively include tantalum nitride, titanium nitride, tantalum, titanium, aluminum or polycrystalline silicon. The capacitor dielectric layer I includes aluminum oxide, zirconium oxide, barium strontium titanate (BST), lead zirconate titanate (PZT), zirconium silicate (ZrSiO₄), hafnium silicon oxide (HfSiO₂), hafnium silicon oxynitride (HfSiON), tantalum oxide or a combination of the above materials. The insulating layer 24 is preferably silicon oxide. The thickness of the first electrode E1 is preferably between 200 and 300 angstroms. The thickness of the second electrode E2 is preferably between 200 and 300 angstroms, and the thickness of the capacitor dielectric layer I is preferably between 40 and 80 angstroms.

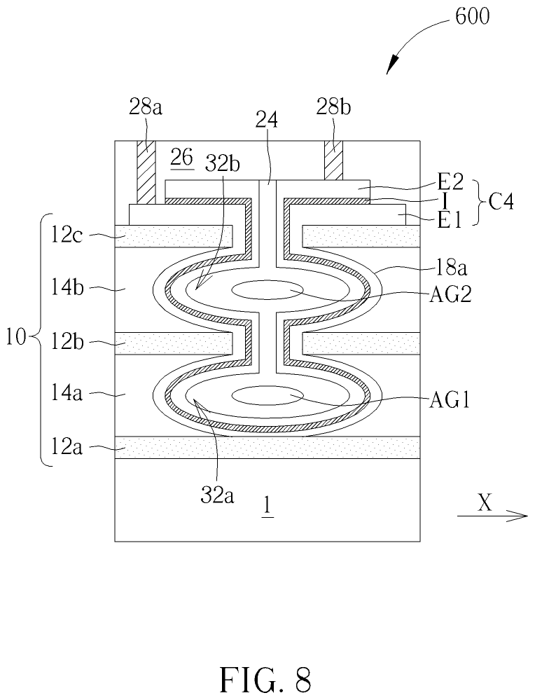

FIG. 8 shows an MIM capacitor structure with a rounded sidewall according to the sixth preferred embodiment of the present invention. Elements which are substantially the same as those in the embodiment of FIG. 8 are denoted by the same reference numerals in FIG. 3; an accompanying explanation is therefore omitted. As shown in FIG. 2 and FIG. 8, an MIM capacitor structure 600 with a rounded sidewall includes a MIM capacitor C4, and the insulating layer 24 between the vertical sidewalls 22b is solid; therefore there is no air gap is this part of the insulating layer 24. In this way, the air gaps AG1/AG2 in the widen region R1 and R2 are not connected.

As shown in FIG. 5, numerous MIM capacitors C1 can be disposed in the stacked layer 10 and connected in series with each other. In details, there are two MIM capacitors C1 disposed in the stack layer 10. The first electrode E1, the capacitor dielectric layer I and the second electrode E2 of the MIM capacitor C1 on the left extend to the trench 18a on the right to serve as the first electrode E1, the capacitor dielectric layer I and the second electrode E2 of the MIM capacitor C1 on the right.

As shown in FIG. 2 and FIG. 4, the difference between the MIM capacitor C2 and the MIM capacitor C1 in FIG. 3 is that the first electrode E1, the capacitor dielectric layer I and the second electrode E2 of MIM capacitor C2 together fill up the widen region R1/R2; therefore is no insulation layer and no air gap in the MIM capacitor structure 200 with a rounded sidewall.

FIG. 6 shows two MIM capacitors C2 disposed in the stacked layer and connected in series. As shown in FIG. 6, numerous MIM capacitors C2 can be disposed in the stacked layer 10 and connected to each other in series. In details, there are two MIM capacitors C2 disposed in the stacked layer 10. The first electrode E1, the capacitor dielectric layer I and the second electrode E2 of the MIM capacitor C2 on the left extend to the trench 18a on the right to serve as the first electrode E1, the capacitor dielectric layer I and the second electrode E2 of the MIM capacitor C2 on the right.

As shown in FIG. 2 and FIG. 7, an MIM capacitor C1 and an MIM capacitor C3 are respectively disposed in trenches 18a/18b. Due to the aforementioned second etching 16b and third etching, the rounded sidewalls 20a/20b of the trench 18a and the rounded sidewalls 30b/30c of the trench 18b are in different material layers. Moreover, the MIM capacitor C1 and the MIM capacitor C3 conformally cover the trenches 18a/18b respectively; therefore, the rounded sidewalls 32a/32b of the MIM capacitor C1 are respectively in the first oxygen-containing silicon compound layer 14a and the second oxygen-containing silicon compound layer 14b, and the rounded sidewalls 34a/34b of the MIM capacitor C3 are respectively in the second silicon-containing material layer 12b and the third silicon-containing material layer 12c. The MIM capacitor C1 and The MIM capacitor C3 are connected in series, that is to say, the first electrode E1, the capacitor dielectric layer I and the second electrode E2 of MIM capacitor C1 extend to the trench 18b on the right to serve as the first electrode E1, the capacitor dielectric layer I and the second electrode E2 of MIM capacitor C3.

The present invention uses the second etching to laterally expand the trench in the stacked layer, thereby forming a MIM capacitor structure with a rounded sidewall, which can increase the surface area of the MIM capacitor and thereby increase the capacitance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A metal-insulator-metal (MIM) capacitor structure with a rounded sidewall, comprising:
a stacked layer, wherein the stacked layer comprises at least a silicon-containing material layer and at least one oxygen-containing silicon compound layer stacked alternately;
a trench disposed in the stacked layer, wherein the trench has a rounded sidewall and a vertical sidewall, and the vertical sidewall and the rounded sidewall are connected to each other;
an MIM capacitor disposed in the trench and contacting the trench;
an insulating layer filling in the trench and sealing up an opening of the trench;
and
an air gap disposed in the insulating layer.

2. The MIM capacitor structure with a rounded sidewall of claim 1, wherein along a horizontal direction parallel to a top surface of the stacked layer, the rounded sidewall is concave toward the stacked layer.

3. The MIM capacitor structure with a rounded sidewall of claim 2, wherein the vertical sidewall is perpendicular to the horizontal direction.

4. The MIM capacitor structure with a rounded sidewall of claim 1, wherein the rounded sidewall is disposed in the oxygen-containing silicon compound layer, and the vertical sidewall is disposed in the silicon-containing material layer.

5. The MIM capacitor structure with a rounded sidewall of claim 4, wherein the oxygen-containing silicon compound layer is silicon oxide, and the silicon-containing material layer is silicon nitride.

6. The MIM capacitor structure with a rounded sidewall of claim 4, wherein the oxygen-containing silicon compound layer is silicon oxide, and the silicon-containing material layer is poly-crystalline silicon, single-crystalline silicon or amorphous silicon.

7. The MIM capacitor structure with a rounded sidewall of claim 1, wherein there is no transistor in the stacked layer.

8. The MIM capacitor structure with a rounded sidewall of claim 1, wherein the rounded sidewall defines a widen region in the trench, and the air gap is disposed in the insulating layer within the widen region.

9. A fabricating method of a metal-insulator-metal (MIM) capacitor structure with a rounded sidewall, comprising:
providing an oxygen-containing silicon compound layer and a silicon-containing material layer;
performing a first etching to etch the oxygen-containing silicon compound layer and the silicon-containing material layer to form a trench;
performing a second etching to etch the oxygen-containing silicon compound layer to laterally expand a portion of a sidewall of the trench to form a rounded sidewall;
after forming the rounded sidewall, forming an MIM capacitor to fill in and contact the trench; and
after forming the MIM capacitor, forming an insulating layer to fill the trench and seal up the opening of the trench, wherein the insulating layer defines an air gap.

10. The fabricating method of an MIM capacitor structure with a rounded sidewall of claim 9, wherein the second etching selectively etches silicon oxide.

11. The fabricating method of an MIM capacitor structure with a rounded sidewall of claim 9, wherein the second etching comprises a wet etching.

12. The fabricating method of an MIM capacitor structure with a rounded sidewall of claim 9, wherein the silicon-containing material layer comprises poly-crystalline silicon, single-crystalline silicon, amorphous silicon or silicon nitride.

13. The fabricating method of an MIM capacitor structure with a rounded sidewall of claim 9, wherein along a horizontal direction parallel to a top surface of the oxygen-containing silicon compound layer, the rounded sidewall is concave toward the oxygen-containing silicon compound layer.
